(19) United States
(12) Patent Application Publication
(10) Pub. No.: US 2008/0003744 A1
(43) Pub. Date: Jan. 3, 2008

(54) METHOD OF MANUFACTURING NAND FLASH MEMORY DEVICE

(75) Inventor: Byoung Ki Lee, Icheon-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/618,714

(22) Filed: Dec. 29, 2006

(30) Foreign Application Priority Data
Jun. 28, 2006 (KR) 10-2006-58548

(51) Int. Cl. H01L 21/336

(52) U.S. Cl. 438/257; 257/E29.3

(57) ABSTRACT

A method of manufacturing a non-volatile memory device includes forming first and second isolation structures in a substrate. A tunnel dielectric layer, a first conductive layer, a first insulating layer, and a second insulating layer are provided between the first and second isolation structures. The first and second insulating layers are removed to expose the first conductive layer. First and second vertical extensions are formed on the first conductive layer to form a U-shape structure. Upper portions of the first and second isolation structures are removed to define second gate trenches, so that each vertical extension has first and second sides exposed. A dielectric layer and a second conductive layer are formed to form a gate structure comprising the first conductive layer, the dielectric layer, and the second conductive layer.

### CROSS-REFERENCES TO RELATED APPLICATIONS

The present application claims priority to Korean patent application number 10-2006-58548, filed on Jun. 28, 2006, which is incorporated by reference in its entirety.

### BACKGROUND OF THE INVENTION

The present invention relates to a NAND flash memory device and, more particularly, to a method of manufacturing a NAND flash memory device, in which the threshold voltage (Vt) shift due to cell interference can be reduced and the programmed threshold voltage Vt can be increased.

Currently, in the manufacturing of NAND flash memory, the space in which a unit active region and a unit field region are formed decreases as the level of integration increases. Thus, as the dielectric layer, the control gate, and the floating gate, are formed within a narrow active space, the distance between gates is narrowed. Accordingly, an interference phenomenon becomes more problematic.

FIG. 1 is a perspective view illustrating a general method of manufacturing a NAND flash memory device by employing a Self-Aligned Shallow Trench Isolation (SASTI).

Referring to FIG. 1, a tunnel oxide layer 11 and a first polysilicon layer 12 are formed over a semiconductor substrate 10. The first polysilicon layer 12 and the tunnel oxide layer 11 are selectively etched by an etch process employing an isolation mask. The semiconductor substrate 10 is etched by using the selectively etched first polysilicon layer 12 as a mask, forming trenches.

An insulating layer, such as a High Density Plasma (HDP) oxide layer, is formed on the resulting structure so that the trenches are gap-filled. The insulating layer is polished by means of a Chemical Mechanical Polishing (CMP) so that the top surface of the first polysilicon layer 12 is exposed, thus forming an isolation layer 13 in each of the trenches.

A second polysilicon layer 14 is formed on the resulting structure. The second polysilicon layer 14 is etched by using a mask, thus forming a floating gate including the first polysilicon layer 12 and the second polysilicon layer 14. A dielectric layer 15 and a conductive layer 16 for a control gate are formed on the resulting structure.

If the floating gate is formed by the above method, the width of the isolation trench decreases as the level of integration increases, and therefore the distance between neighboring floating gates also decreases. This leads to the occurrence of an interference phenomenon due to neighboring cells. The interference phenomenon can occur between cells in a word line direction and a string cell direction. The interference phenomenon occurring between cells in the string cell direction is generated since the HDP oxide layer existing between the first polysilicon layers serves as a dielectric material. The interference phenomenon occurring between the cells in the word line direction is generated since the HDP oxide layer existing between the gates serves as a dielectric material.

FIG. 2 is a graph illustrating the relationship between the programmed threshold voltage Vt and the threshold voltage (Vt) shift due to interference as the size of a device is decreased.

In FIG. 2, curve “a” is a plot indicating the threshold voltage (Vt) shift due to interference of a cell verses device size, and curve “b” is a plot indicating the programmed threshold voltage (Vt) verses device size. From FIG. 2, it can be seen that in sub-60 nm devices, both the programmed threshold voltage Vt and the threshold voltage (Vt) shift due to interference exceed the limit values of a device.

### BRIEF SUMMARY OF THE INVENTION

The present invention is directed towards a method of manufacturing a NAND flash memory device, which can decrease the threshold voltage (Vt) shift due to interference of a cell by decreasing the footprint of the floating gate, and can increase the program threshold voltage Vt by increasing the contact area between the floating gate and the control gate.

A method of manufacturing a NAND flash memory device includes the steps of; etching a tunnel oxide layer, a first polysilicon layer, a buffer oxide layer, a nitride layer and a portion of a semiconductor substrate, all of which are laminated over a semiconductor substrate, thus forming trenches; forming an insulating layer within each of the trenches to form an isolation layer; sequentially removing the exposed nitride layer and the exposed buffer oxide layer; forming spacers on sidewalls of the isolation layer and partially removing a top surface of the isolation layer to control an EFH of the isolation layer; and forming a dielectric layer, a second polysilicon layer and a conductive layer on the entire surface of the resulting structure.

In one embodiment, a method of manufacturing a flash memory device includes etching a tunnel dielectric layer, a first polysilicon layer, a buffer oxide layer, a nitride layer and a portion of a semiconductor substrate to form first and second isolation trenches. An insulating layer is formed within the first and second isolation trenches to form first and second isolation structures, respectively, wherein the nitride layer, buffer oxide layer, the first polysilicon layer, and the tunnel dielectric layer being defined between the first and second isolation structures. The nitride layer and the buffer oxide layer defined between the first and second isolation structures are removed to define a first gate trench. First and second vertical extensions are formed within the first gate trench, the first vertical extension provided proximate to a sidewall of the first isolation structure, the second vertical extension provided proximate to a sidewall of the second isolation structure, the first and second vertical extensions contacting the first polysilicon layer. Upper portions of the first and second isolation structures are removed to define second gate trenches, so that each vertical extension has first and second sides exposed. A dielectric layer and a second polysilicon layer are formed within the first gate trench and the second gate trenches.

In one embodiment, a method of manufacturing a non-volatile memory device includes forming first and second isolation structures in a substrate. A tunnel dielectric layer, a first conductive layer, a first insulating layer, and a second insulating layer are provided between the first and second isolation structures. The first and second insulating layers are removed to expose the first conductive layer. First and second vertical extensions are formed on the first conductive layer to form a U-shape structure. Upper portions of the first and second isolation structures are removed to define second gate trenches, so that each vertical extension has first and second sides exposed. A dielectric layer and a second conductive layer are formed to form a gate structure comprising the first conductive layer, the dielectric layer, and the second conductive layer.

In one embodiment, the first and second isolation structures are formed after the tunnel dielectric layer and the first conductive layer. The first conductive layer includes polysilicon. The first insulating layer is provided as an etch stop layer, so that the second insulating layer can be removed without damaging the first conductive layer. The first insulating layer is oxide-based, and the second insulating layer is nitride-based.

### BRIEF DESCRIPTION OF THE DRAWINGS

FIG. 1 is a perspective view illustrating a method of manufacturing a conventional NAND flash memory device.

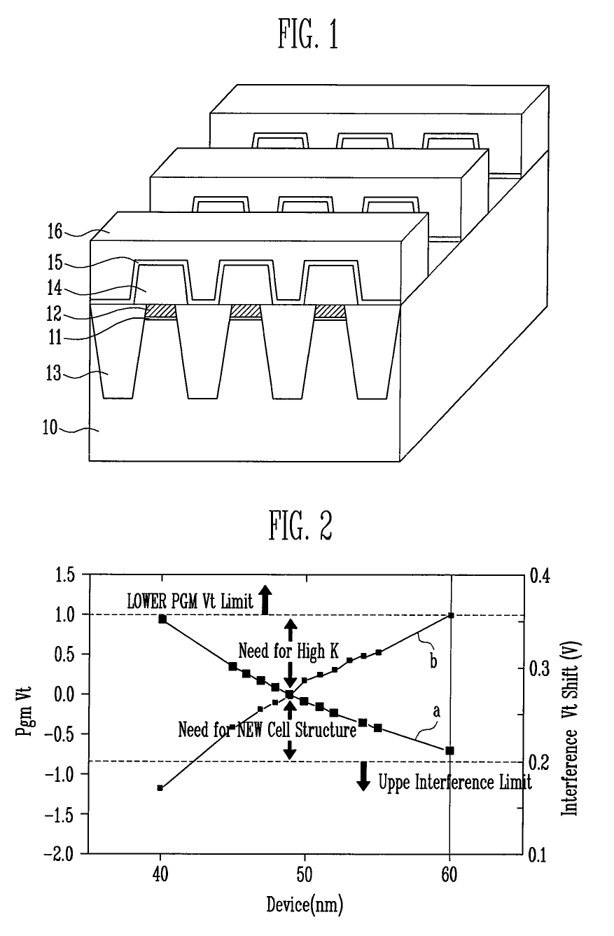

FIG. 2 is a graph illustrating the relationship between the programmed threshold voltage Vt and the threshold voltage (Vt) shift due to interference as the size of the device is decreased.

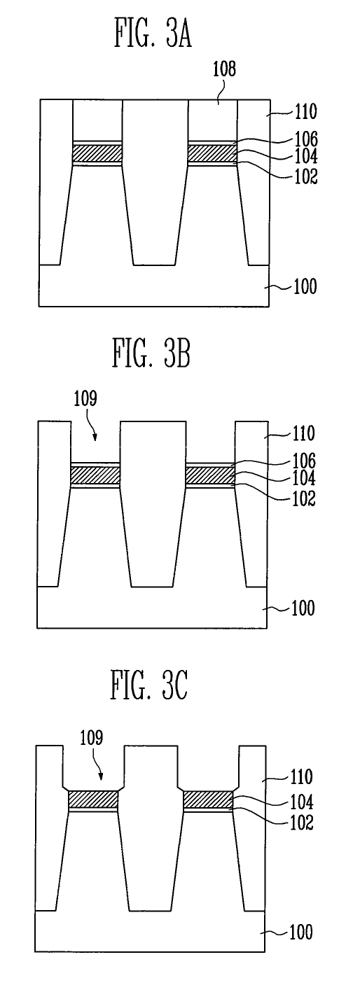

FIGS. 3A to 3F are cross-sectional views illustrating a method of manufacturing a NAND flash memory device by employing a STI according to an embodiment of the present invention.

### DESCRIPTION OF SPECIFIC EMBODIMENTS

A specific embodiment of the present patent will be described with reference to the accompanying drawings.

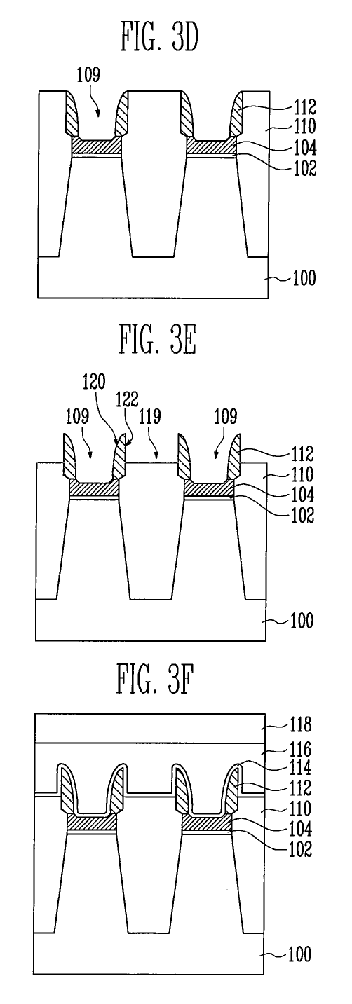

Referring to FIG. 3A, a tunnel oxide layer (or tunnel dielectric layer) 102, a first polysilicon layer 104 for a floating gate, a buffer oxide layer 106 and a nitride layer 108 are formed over a semiconductor substrate 100. The layers 102, 104, and 106 are formed sequentially in the present implementation. The nitride layer 108, the buffer oxide layer 106, the first polysilicon layer 104, the tunnel oxide layer 102 and a portion of the semiconductor substrate 100 are etched to form trenches. The nitride layer 108 is formed to a thickness of 500 to 900 angstroms.

A sidewall oxide layer is formed within each of the trenches (not shown). An insulating layer is formed on the resulting structure so that the trenches are gap-filled. The insulating layer can be formed from a HDP oxide layer. The insulating layer is polished so that a top surface of the nitride layer 108 is exposed, thus forming an isolation structure 110 within each trench.

Referring to FIG. 3B, the nitride layer 108 is removed to expose the buffer oxide layer 106. A wet etch process is performed to remove the nitride layer 108 in the present implementation. A trench 109 is defined between two adjacent isolation structures. When removing the nitride layer 108, an etch target depth can be set to 150 to 170% of a total deposition thickness to ensure that the nitride layer is substantially removed from the buffer oxide layer. The nitride etch step performed is provided with high selectivity to the oxide, so that only the buffer oxide layer 106 is only partially removed at the top. The buffer oxide layer 106 remains to a thickness of 20 to 40 angstroms. The buffer oxide layer 106 protects the first polysilicon layer 104 from the nitride etch process.

Referring to FIG. 3C, the remaining buffer oxide layer 106 is removed, e.g., by a wet etch process employing BOE or HF. At this time, the buffer oxide layer 106 is over-etched to a thickness of 40 to 80 angstroms. Due to the etch selectivity of the buffer oxide layer 106 and the first polysilicon layer 104, only a small amount of the polysilicon layer 104 is removed. A significant amount of the sidewalls of the isolation layer 110 is etched away.

Referring to FIG. 3D, a silicon layer is formed on the resulting structure. The silicon layer can be formed to a thickness of 100 to 300 angstroms. In the present implementation, the silicon layer is doped amorphous silicon. The silicon layer is blanket etched to form vertical extensions (or spacers) 112 on the sidewalls of the isolation layer 110. The vertical extensions 112 and the first polysilicon layer 104 together resemble a U-shape structure. At the time of the etch, the silicon layer is over-etched to a thickness of 200 to 450 angstroms, so that the top portion of the top first polysilicon layer 104 is also etched.

Referring to FIG. 3E, the top surface of the isolation layer 110 is partially etched by a wet etch process using BOE or HF in order to control the EFH of the isolation layer 110. A trench 119 is from above each isolation structure 110. This increases the exposed surfaces of the vertical extensions 112. Each vertical extension 112 has a first side 120 that is facing the trench 109 and a second side 122 on the opposing side of the first side 120.

Referring to FIG. 3F, A dielectric layer 114, a second polysilicon layer 116 for a control gate and a conductive layer 118 are formed on the resulting structure. These layers 114, 116, and 118 are formed sequentially in the present implementation.

If the floating gate is formed as described above, the contact area of the floating gate and the control gate can be increased. Accordingly, the coupling ratio and the programmed threshold voltage Vt can be increased. Furthermore, since this allows the footprint of the polysilicon layer for the floating gate to be reduced, the threshold voltage (Vt) shift due to interference of a cell can be decreased. The present embodiment may be implemented with various non-volatile memory devices including multi-level cell flash memory devices. The present embodiment may be used to scale down to flash memory devices of 50 nm or less.

The above embodiment of the present invention is illustrative and not limitative. Various alternatives and equivalents are possible. Other additions, subtractions, or modifications are obvious in view of the present disclosure and are intended to fall within the scope of the appended claims.

What is claimed is:

1. A method of manufacturing a flash memory device, the method comprising:
etching a tunnel dielectric layer, a first polysilicon layer, a buffer oxide layer, a nitride layer and a portion of a semiconductor substrate to form first and second isolation trenches;
forming an insulating layer within the first and second isolation trenches to form first and second isolation structures, respectively, wherein the nitride layer, buffer oxide layer, the first polysilicon layer, and the tunnel dielectric layer being defined between the first and second isolation structures;
removing the nitride layer and the buffer oxide layer defined between the first and second isolation structures to define a first gate trench;
forming first and second vertical extensions within the first gate trench, the first vertical extension provided proximate to a sidewall of the first isolation structure, the second vertical extension provided proximate to a sidewall of the second isolation structure, the first and second vertical extensions contacting the first polysilicon layer;
removing upper portions of the first and second isolation structures to define second gate trenches, so that each vertical extension has first and second sides exposed; and
forming a dielectric layer and a second polysilicon layer within the first gate trench and the second gate trenches.

2. The method of claim 1, wherein the nitride layer is formed to a thickness of 500 to 900 angstroms.

3. The method of claim 1, wherein the buffer oxide layer remains to a thickness of 20 to 40 angstroms after the nitride layer is removed.

4. The method of claim 1, wherein the buffer oxide layer is removed by a wet etch process to expose the first polysilicon layer.

5. The method of claim 4, wherein the wet etch process uses BOE or HF.

6. The method of claim 1, wherein the sidewalls of the first and second isolation structures are removed when the buffer oxide is removed.

7. The method of claim 6, wherein the first and second vertical extensions are formed by forming a silicon layer on a resulting structure after the buffer oxide layer and the sidewalls of the first and second isolation structures are removed and blanket-etching the silicon layer.

8. The method of claim 7, wherein the silicon layer is formed to a thickness of 100 to 300 angstroms by using a doped amorphous silicon layer.

9. The method of claim 7, wherein a top surface of the first polysilicon layer is partially etched at the time of the blanket-etch process.

10. The method of claim 1, the first and second vertical extensions and the first polysilicon layer together form a U-shape structure.

11. A method of manufacturing a non-volatile memory device, the method comprising:
forming first and second isolation structures in a substrate;
providing a tunnel dielectric layer, a first conductive layer, a first insulating layer, and a second insulating layer between the first and second isolation structures;
removing the first and second insulating layers to expose the first conductive layer;
forming first and second vertical extensions on the first conductive layer to form a U-shape structure;
removing upper portions of the first and second isolation structures to define second gate trenches, so that each vertical extension has first and second sides exposed; and
forming a dielectric layer and a second conductive layer to form a gate structure comprising the first conductive layer, the dielectric layer, and the second conductive layer.

12. The method of claim 11, wherein the first and second isolation structures are formed after the tunnel dielectric layer and the first conductive layer.

13. The method of claim 11, wherein the first conductive layer includes polysilicon.

14. The method of claim 11, wherein the first insulating layer is provided as an etch stop layer, so that the second insulating layer can be removed without damaging the first conductive layer.

15. The method of claim 14, wherein the first insulating layer is oxide-based, and the second insulating layer is nitride-based.
